(19) United States
(12) Patent Application Publication
(10) Pub. No.: US 2025/0270697 A1
(43) Pub. Date: Aug. 28, 2025

(54) BOTTOM-UP DIRECTIONAL ATOMIC LAYER DEPOSITION (ALD)

(71) Applicant: Tokyo Electron Limited, Tokyo (JP)

(72) Inventor: Toshihiko IWAO, Nirasaki City (JP)

(73) Assignee: Tokyo Electron Limited, Tokyo (JP)

(21) Appl. No.: 18/589,570

(22) Filed: Feb. 28, 2024

(51) Int. Cl. C23C 16/455; C23C 16/34; H01L 21/02

(52) U.S. Cl. CPC C23C 16/45553; C23C 16/345; C23C 16/45542; H01L 21/02211; H01L 21/0228; C23C 2222/20

(57) ABSTRACT

A method of film deposition is provided. The method includes providing a wafer including a patterned structure having a top, a bottom and a sidewall. A film can be formed on the wafer by a cyclical deposition process including a cycle of contacting the wafer with a first reactant comprising a silicon precursor to form an intermediate layer over the patterned structure of the wafer, generating a plasma comprising H⁺ ions to modify the intermediate layer by delivering the H⁺ ions anisotropically towards the top and the bottom of the patterned structure, and contacting the wafer with a second reactant to form a material layer. The silicon precursor includes a silicon-nitrogen bond and includes no halogen. The second reactant includes at least one selected from the group consisting of a nitrogen precursor, an oxygen precursor and a carbon precursor.

### FIELD OF THE INVENTION

This disclosure relates generally to methods of microfabrication and more specifically to film deposition.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area and yet are running into greater challenges as miniaturization continues with three-dimensional (3D) semiconductor structure and topography.

### SUMMARY

The present disclosure relates to a method of film deposition and an apparatus of executing the same.

According to a first aspect of the disclosure, a method of film deposition is provided. The method includes providing a wafer including a patterned structure having a top, a bottom and a sidewall. A film is formed on the wafer by a cyclical deposition process including a cycle of contacting the wafer with a first reactant including a silicon precursor to form an intermediate layer over the patterned structure of the wafer, generating a plasma including H⁺ ions to modify the intermediate layer by delivering the H⁺ ions anisotropically towards the top and the bottom of the patterned structure, and contacting the wafer with a second reactant to form a material layer. The silicon precursor includes a silicon-nitrogen bond and includes no halogen. The second reactant includes at least one selected from the group consisting of a nitrogen precursor, an oxygen precursor and a carbon precursor.

In some embodiments, the silicon precursor consists of silicon (Si), nitrogen (N), hydrogen (H) and carbon (C) or consists of Si, N and H.

In some embodiments, the silicon precursor includes at least one of trisilylamine (TSA) or a molecule conforming to a formula of Si(NR¹R²)ₙ(R³)₄₋ₙ, where n is 1, 2, 3 or 4, and R¹, R², and R³ are each independently a hydrogen atom or an alkyl group having 1-18 carbon atoms.

In some embodiments, the silicon precursor includes at least one selected from the group consisting of TSA, bis(tertiary-butylamino) silane (BTBAS), bis(diethylamino) silane (BDEAS) and bis(dimethylamino)dimethylsilane (BDMADMS).

In some embodiments, the plasma is generated from a gas including at least one selected from the group consisting of H₂ and a hydrocarbon.

In some embodiments, the gas includes at least one selected from the group consisting of H₂, benzene, a benzene derivative having 7 to 10 carbon atoms, and an alkane having 1 to 18 carbon atoms.

In some embodiments, the gas includes H₂, CH₄ or a combination thereof.

In some embodiments, the plasma further includes H₂⁺ and H₃⁺ ions.

In some embodiments, the plasma is generated at a frequency of 100 MHz to 10 GHz.

In some embodiments, the H⁺ ions are substantially unidirectional so that the H⁺ ions are delivered substantially towards the top and the bottom of the patterned structure, relative to the sidewall of the patterned structure.

In some embodiments, the H⁺ ions have a substantially monotonic energy distribution that is configured to promote film deposition at the top and the bottom of the patterned structure.

In some embodiments, the cyclical deposition process includes repeating the cycle for at least one more time.

In some embodiments, the film is thicker at the top and the bottom of the patterned structure than at the sidewall of the patterned structure.

In some embodiments, the plasma is generated before or while the wafer is contacted with the second reactant.

In some embodiments, the cyclical deposition process is executed at a temperature of no higher than 500° C.

In some embodiments, the cyclical deposition process includes atomic layer deposition.

In some embodiments, —NH₂ surface groups are formed on the patterned structure of the wafer.

In some embodiments, the material layer includes one selected from the group consisting of silicon nitride, silicon oxide, silicon oxynitride and silicon carbide.

In some embodiments, the material layer includes silicon nitride, and the second reactant includes a nitrogen precursor.

According to a second aspect of the disclosure, an apparatus is provided. The apparatus includes a controller including a processor that is programmed to provide a wafer including a patterned structure having a top, a bottom and a sidewall and form a film on the wafer by a cyclical deposition process. The cyclical deposition process includes a cycle of contacting the wafer with a first reactant including a silicon precursor to form an intermediate layer over the patterned structure of the wafer, generating a plasma including H⁺ ions to modify the intermediate layer by delivering the H⁺ ions anisotropically towards the top and the bottom of the patterned structure, and contacting the wafer with a second reactant to form a material layer. The silicon precursor includes a silicon-nitrogen bond and includes no halogen. The second reactant includes at least one selected from the group consisting of a nitrogen precursor, an oxygen precursor and a carbon precursor.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a schematic of a plasma tool in accordance with some embodiments of the present disclosure.

FIG. 1B shows a vertical cross-sectional schematic of a wafer in accordance with some embodiments of the present disclosure.

FIG. 2 shows a block diagram of a film deposition process in accordance with some embodiments of the present disclosure.

FIGS. 3A and 3B respectively show a vertical cross-sectional schematic and view of a wafer in accordance with some embodiments of the present disclosure.

FIGS. 3C and 3D respectively show a vertical cross-sectional schematic and view of a wafer in related examples.

FIG. 4A shows a schematic of an atomic layer deposition (ALD) process in accordance with some embodiments of the present disclosure.

FIG. 4B shows an energy graph of the ALD process in FIG. 4A in accordance with some embodiments of the present disclosure.

FIG. 5A shows an ion energy distribution of a plasma in accordance with some embodiments of the present disclosure.

FIG. 5B shows an ion energy distribution function of a plasma in accordance with some embodiments of the present disclosure.

FIG. 5C shows an ion angular distribution function of the plasma in FIG. 5B in accordance with some embodiments of the present disclosure.

FIG. 6 shows a flow chart of a film deposition process in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

As noted in the Background, scaling efforts are running into greater challenges with three-dimensional (3D) semiconductor structure and topography, especially on the scale of sub-30 nm or even single-digit nanometers. Precise control of film thickness is therefore desirable and crucial. Atomic layer deposition (ALD) is capable of producing very thin, conformal films with control of the thickness and composition of the films possible at the atomic level.

For a 3D topography such as a trench, a hole or a slit, ALD can be used to form one or more films to fill the gap. However, a void or seam is often seen in the ALD film(s) within the filled space. Ideal V-shaped ALD is difficult in terms of effective topological growth inhibition. Particularly for ALD of silicon nitride (SiN), low temperature SiN gap fill often comes with the problem of air voids or seams in the filled space.

Techniques herein enable void-free or seam-free ALD deposition by combining relatively low ion energy of very high frequency (VHF) plasma and directional bombardment of hydrogen ions. VHF plasma provides substantially lower ion energy than conventional plasma induced at 13 MHz, 27 MHz, 40 MHz and the like. Hydrogen ions produced by VHF plasma tend to have anisotropic velocity. Therefore, when the hydrogen ions are delivered to a top and a bottom of a 3D topography relative to a sidewall, topologically differentiated growth can be achieved, with improved quality at relatively low temperature.

According to aspects of the disclosure, a SiN film is formed by first using a silicon precursor that contains silicon (Si) and nitrogen (N) and termination of amine base or hydrocarbon base, excluding halogen atoms. Then in a film modification step, plasma is generated above 100 MHz (e.g. VHF, ultra-high frequency (UHF) or microwave frequency) to reduce ion energy induced damage. The generated plasma gas is configured to generate hydrogen ions (e.g. H⁺ ions) for film modification. H⁺ ions can provide monotonic energy and anisotropic velocity relative to wafer horizon. Particularly, since some silicon precursors require ion bombardment energy to enhance the growth, anisotropic H⁺ ions can thus provide the kinetic energy only on the top and bottom surfaces of a 3D topological shape.

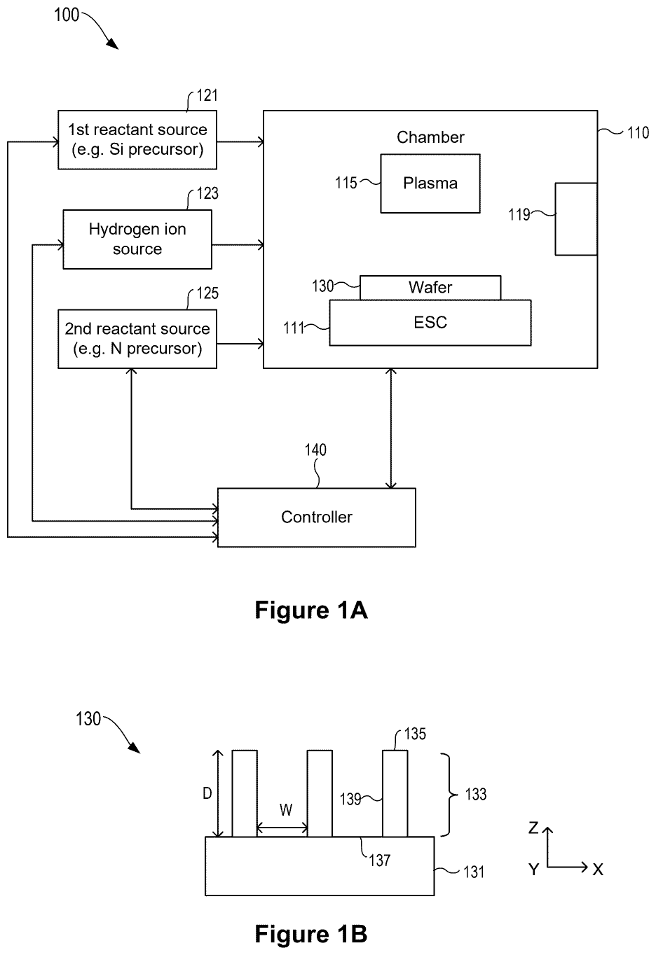

FIG. 1A shows a schematic of a plasma system (referred to as a system 100 hereinafter) in accordance with some embodiments of the present disclosure. As shown, the system 100 includes at least one plasma processing chamber (referred to as a chamber 110 hereinafter). In the chamber 110, a wafer 130 can be placed on an electrostatic chuck (ESC) 111. The chamber 110 can be configured to receive or generate a plasma 115 for the wafer 130. One or more sensors 119 can be used to characterize/monitor the wafer 130 and/or the plasma 115.

The chamber 110 can be coupled to a first reactant source 121 by conduits, pipes or the like and receive a first reactant (e.g. a silicon precursor) from the first reactant source 121. The first reactant source 121 may be coupled to a manifold, valve control system, mass flow control system or the like to release the first reactant in a gaseous form. In some embodiments, the first reactant is liquid or solid under room temperature and standard atmospheric pressure conditions and can be vaporized within a reactant source vacuum vessel, which may be maintained at or above a vaporizing temperature within a precursor source chamber. Accordingly, the vaporized precursor may be transported with a carrier gas (e.g. an inactive or inert gas) and then fed into the chamber 110 through a conduit. In other embodiments, the first reactant may be a vapor under standard conditions. Accordingly, the first reactant may be stored in a gas cylinder and need no carrier gas.

Similarly, the chamber 110 can be coupled to a second reactant source 125 and receive a second reactant (e.g. a nitrogen precursor) from the second reactant source 125. Additionally, the chamber 110 can be coupled to a carrier gas source, an inert gas source, a purge gas source and the like (not shown for simplicity purposes). The descriptions have been provided above and will be omitted herein for simplicity purposes.

In a non-limiting example, the system 100 is configured to execute atomic layer deposition (ALD) of silicon nitride (SiN) on the wafer 130. Accordingly, the first reactant source 121 and the second reactant source 125 respectively include a silicon precursor and a nitrogen precursor. The nitrogen precursor can include, but are not limited to, N₂, NH₃ and N₂H₄.

The silicon precursor includes at least one silicon-nitrogen bond and includes no halogen i.e. fluorine (F), chlorine (Cl), bromine (Br), iodine (I), astatine (At) and tennessine (Ts). The silicon precursor may include at least one substitute group selected form the group consisting of a silyl group, an amine group and an alkyl group. For instance, a silyl group can be bonded to a nitrogen atom. An amine group can be bonded to a silicon atom. An alkyl group can be bonded to a nitrogen atom and/or a silicon atom.

In one embodiment, the silicon precursor consists of four elements: silicon (Si), nitrogen (N), hydrogen (H) and carbon (C). The silicon precursor may conform to the formula of Si(NR¹R²)ₙ(R³)₄₋ₙ, where n is 1, 2, 3 or 4. R¹, R², and R³ are each independently a hydrogen atom or an alkyl group that is a straight or branched chain. Independently R¹, R², and R³ are preferably a hydrogen atom or an alkyl group having 1-18 carbon atoms, preferably 1-12 carbon atoms, preferably 1-6 carbon atoms, preferably a methyl group, an ethyl group, a propyl group or a butyl group, straight or branched. Examples include, but are not limited to, bis(tertiary-butylamino) silane (BTBAS), bis(diethylamino)-silane (BDEAS) and bis(dimethylamino)dimethylsilane (BDMADMS). In another embodiment, the silicon precursor consists of three elements: Si, N and H. Examples include, but are not limited to, trisilylamine (TSA). Examples of the silicon precursor discussed herein can be used individually or in any combination.

Further, the chamber 110 can be coupled to a hydrogen ion source 123 and receive a gas from the hydrogen ion source 123, similar to descriptions above regarding the first reactant source 121. The gas can be used to generate a plasma containing hydrogen ions in the chamber 110. The gas can include H₂ and/or a hydrocarbon. In some embodiments, the hydrocarbon may include an alkane that is a straight or branched chain and conforms to the formula of CₙH₂ₙ₊₂, where n is an integer of 1 to 18, preferably 1 to 12, preferably 1 to 6, preferably 1, 2, 3 or 4. The hydrocarbon can optionally include at least one carbon-carbon double bond and/or at least one carbon-carbon triple bond. Preferably, the gas includes H₂ and/or CH₄. In some embodiments, the hydrocarbon may include an arene such as benzene or a derivative thereof. The derivative may include one or more substitute groups on a benzene ring and can have 7 to 10 carbon atoms, preferably 7 or 8 carbon atoms. Such substitute groups can have an alkyl group that is a straight or branched chain having 1, 2, 3 or 4 carbon atoms, optionally having at least one carbon-carbon double bond and/or at least one carbon-carbon triple bond. For instance, the arene can include benzene, toluene, xylene, styrene and/or the like. Examples of the gas discussed herein can be used individually or in any combination.

In other embodiments, the hydrogen ion source 123 can include a remote plasma source that generates a plasma containing hydrogen ions. Accordingly, the chamber 110 is configured to receive the plasma from the hydrogen ion source 123.

Additionally, the sensors 119 can include an optical emission spectroscopy (OES) sensor, a voltage peak-to-peak (VPP) sensor, an ion flux sensor, a mass spectrometer, a temperature sensor, a pressure sensor, a reflectometer, an ellipsometer and/or other sensors as known by one skilled in the art. While shown to be installed on a sidewall of the chamber 110 in the example of FIG. 1A, locations of the sensors 119 are not particularly limited. That is, the sensors 119 can each independently be placed inside or outside the chamber 110, in contact with, in proximity to, distant from or within the wafer 130, and the like.

Further, a controller 140 may optionally be included in the example of FIG. 1A. Components of one or more corresponding plasma tools can be connected to and controlled by the controller 140 that may optionally be connected to a corresponding memory storage unit and user interface (all not shown for simplicity purposes). Various plasma-processing operations can be executed via the user interface, and various plasma processing recipes and operations can be stored in a storage unit. Accordingly, a given wafer can be processed within a plasma chamber with various microfabrication techniques.

The controller 140 may be coupled to various components of the corresponding plasma tool(s) to receive inputs from and provide outputs to the components. For example, the controller 140 can be configured to receive sensor data from the sensors 119 to monitor gas species and/or the wafer 130 in the chamber 110 and determine flow rates of precursors. The controller 140 can also be configured to adjust knobs and control settings for the corresponding plasma tool(s), or more specifically the chamber 110, the first reactant source 121, the hydrogen ion source 123 and the second reactant source 125. Of course the adjustment(s) can be manually made as well.

The controller 140 can be implemented in a wide variety of manners. In one example, the controller 140 is a computer. In another example, the controller 140 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

Note that the system 100 may include a capacitively-coupled plasma processing apparatus, inductively-coupled plasma processing apparatus, microwave plasma processing apparatus, electron cyclotron resonance (ECR) plasma processing apparatus, or other types of processing systems or combination of systems. Thus, it will be recognized by those skilled in the art that the techniques described herein may be utilized with any of a wide variety of plasma processing systems. The system 100 can be used for a wide variety of operations including, but not limited to, etching, deposition, cleaning, plasma polymerization, plasma-enhanced chemical vapor deposition (PECVD), atomic layer deposition (ALD), atomic layer etch (ALE), and the like. Particularly, ALD is used in this disclosure for illustrative purposes and is not limiting. Structures of plasma tools and ALD tools are both well known to one skilled in the art. It will be recognized that different and/or additional plasma process systems may be implemented while still taking advantage of the techniques described herein.

FIG. 1B shows a vertical cross-sectional schematic of the wafer 130 in accordance with some embodiments of the present disclosure. As illustrated, the wafer 130 can include a substrate 131 and a patterned structure 133 formed thereon. The patterned structure 133 can have a top 135, a bottom 137 and a sidewall 139. The top 135 and the bottom 137 of the patterned structure 133 are substantially parallel to each other. The patterned structure 133 can include a trench, a hole, a slit, a gap, an opening or any other topography that has a vertical cross-sectional view as shown. For example, the patterned structure 133 can include parallel lines of material (e.g. metal and/or dielectric) with gaps in between. The patterned structure 133 can have a high aspect ratio in that a ratio of a depth D of the patterned structure 133 to a width W of the bottom 137 is in a range of 3 to 20, such as 3, 5, 7, 10, 12, 15, 18, 20 or any value therebetween.

In one embodiment, the substrate 131 and the patterned structure 133 include different materials. The wafer 130 may further include one or more layers (not shown) formed between the substrate 131 and the patterned structure 133. In another embodiment, the substrate 131 and the patterned structure 133 include the same material. The substrate 131 and the patterned structure 133 can therefore be a monolithic piece. In a non-limiting example, the substrate 131 includes silicon while the patterned structure 133 includes —NH₂ surface groups on the top 135, the bottom 137 and the sidewall 139. The material of the patterned structure 133 is not particularly limited and can include, but is not limited to, silicon, silicon oxide, silicon nitride, silicon oxynitride and silicon carbide.

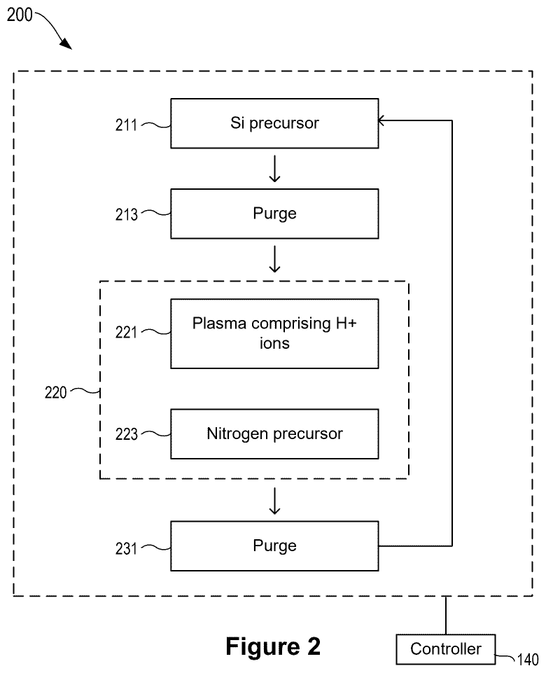

FIG. 2 shows a block diagram of a process 200 of atomic layer deposition (ALD) of silicon nitride (SiN) in accordance with some embodiments of the present disclosure. The process 200 can be executed by the system 100 and the like.

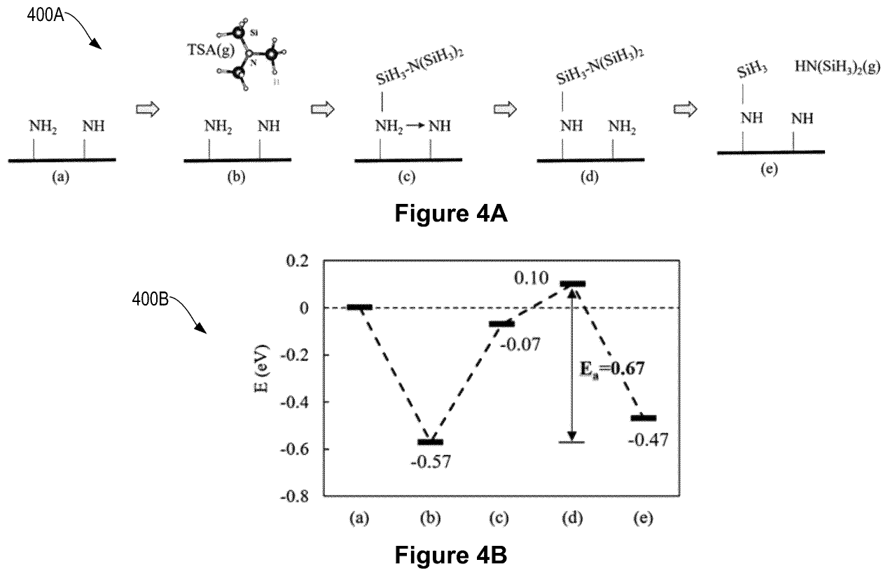

In block 211, the aforementioned silicon precursor is introduced into the chamber 110 as the first reactant. Trisilylamine (TSA) will be used herein as one example of the silicon precursor for illustrative purposes. As discussed earlier, the patterned structure 133 of the wafer 130 can include —NH₂ surface groups on the top 135, the bottom 137 and the sidewall 139. Therefore, TSA can react with the —NH₂ surface groups to form an intermediate layer, which will be explained further in FIGS. 4A and 4B. Subsequently in block 213, the chamber 110 is purged with a purge gas to remove unreacted TSA.

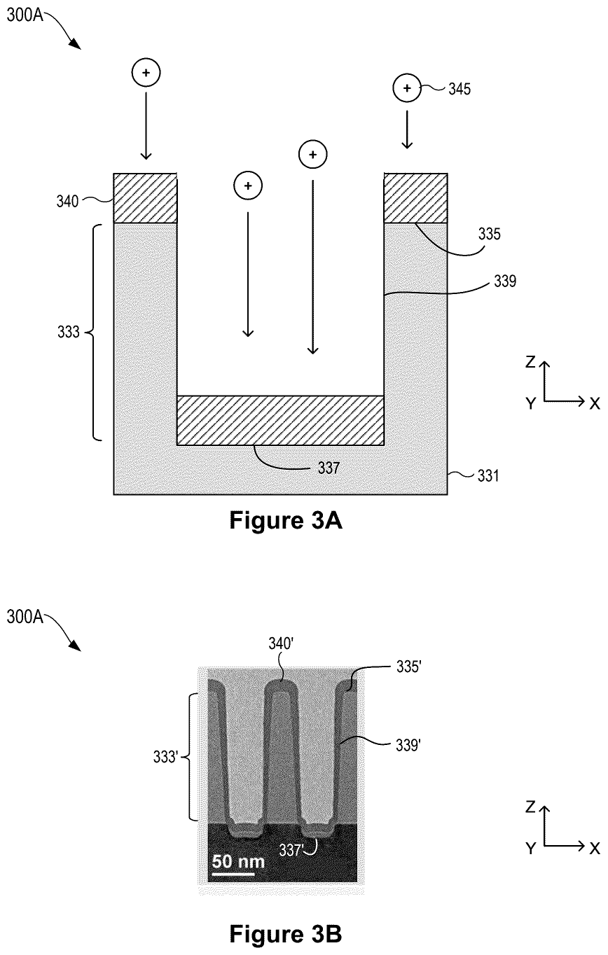

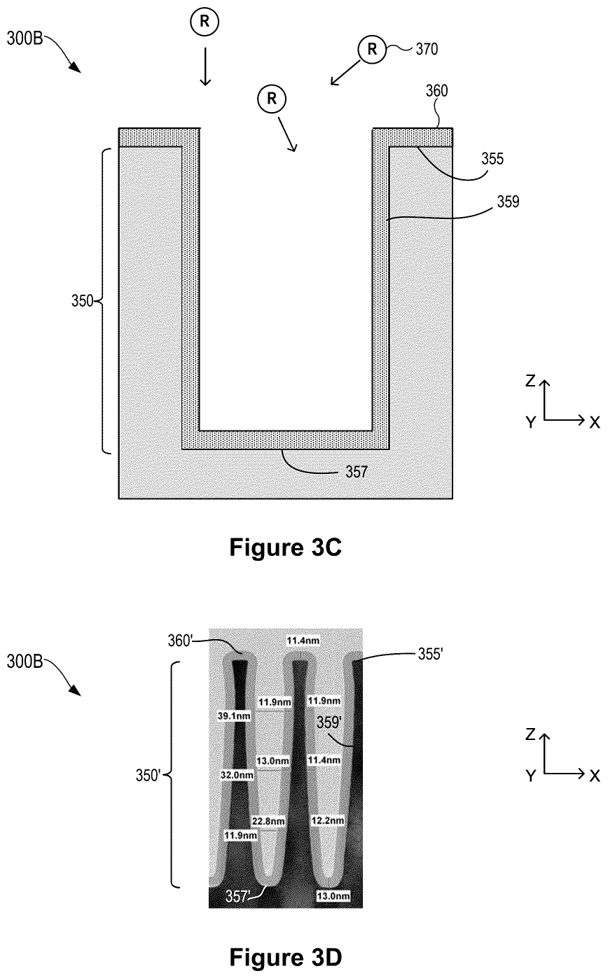

In block 221, a plasma containing hydrogen ions (e.g. H⁺, H₂⁺ and H₃⁺ ions) is generated to modify the intermediate layer by delivering the hydrogen ions anisotropically towards the top 135 and the bottom 137 of the patterned structure 133. As shown in FIG. 3A, a wafer 300A includes a substrate 331 and a patterned structure 333 having a top 335, a bottom 337 and a sidewall 339. The patterned structure 333 corresponds to the patterned structure 133. As illustrated, H⁺ ions 345 can be delivered substantially in the −Z direction, therefore selectively bombarding the top 341 and the bottom 337, relative to the sidewall 339. Since the anisotropic ion bombardment of the hydrogen ions can promote film growth, film growth rate is higher at the top 335 and the bottom 337 than at the sidewall 339. Therefore, more material 340 can be formed at the top 335 and the bottom 337 than at the sidewall 339.

Referring back to FIG. 2, in block 223, a nitrogen precursor is introduced into the chamber 110 as the second reactant. The nitrogen precursor can react with the intermediate layer to form a material layer of SiN. Note that block 221 and block 223 can be executed simultaneously within block 220. Alternatively, block 221 can be started or executed prior to block 223.

In block 231, the chamber 110 is purged with a purge gas to remove the (remaining unreacted) nitrogen precursor. A first cycle of ALD is thus accomplished by blocks 211, 213, 221, 223 and 231. The process 200 may then return to block 211 to repeat the first cycle for at least one more time to form a film. The film may be thicker at the top 135 and the bottom 137 than at the sidewall 139 due to different film growth rates. For example as shown in FIG. 3B, a film 340′ is thicker at a top 335′ and a bottom 337′ of a patterned structure 333′ than at a sidewall 339′ of the patterned structure 333′. Note that similar or identical components are labeled with similar or identical numerals unless specified otherwise. For example, the patterned structure 333′ corresponds to the patterned structure 333.

Referring back to FIG. 2, the process 200 can be terminated when a predetermined number of ALD cycles is finished, when a target local film thickness is reached, or when the patterned structure 133 has been filled or overfilled. In some embodiments, a second cycle can be accomplished by blocks 211, 213, 223 and 231. The process 200 may include both the first cycle and the second cycle executed and repeated in any sequence or order.

While SiN is shown herein for illustrative purposes, it should be understood that techniques herein are also applicable to other films including, but not limited to, silicon oxide, silicon oxynitride and silicon carbide. Accordingly in block 223, another precursor, such as an oxygen precursor and/or a carbon precursor, may be introduced into the chamber 110.

In some embodiments, the controller 140 may optionally be coupled to various components of the process 200 to receive inputs from and provide outputs to the components. For example, the controller 140 can be configured to receive gas flow rate data from blocks 211, 213, 221, 223 and 231 as well as control gas flow rates in blocks 211, 213, 221, 223 and 231. That is to say, the controller 140 can be configured to implement and monitor blocks 211, 213, 221, 223 and 231. While not shown, the controller 140 can also be configured to determine when to terminate the process 200 by determining whether the predetermined number of ALD cycles is finished, when the target local film thickness is reached by measurement of the sensors 119, or when the patterned structure 133 has been filled or overfilled by measurement of the sensors 119. Of course, one or more functions of the controller 140 can also be manually accomplished.

FIG. 3C shows a vertical cross-sectional schematic of a wafer 300B in related examples. A conformal film 360 is grown over a patterned structure 350. That is to say, the conformal film 360 has a substantially identical film thickness along the patterned structure 350 including a top 355, a bottom 357 and a sidewall 359. For example, the conformal film 360 can be a SiN film formed by ALD using precursors of dichlorosilane (DCS) and NH₃. The ALD chemistry of DCS has a different mechanism in which film growth is driven by radicals 370. Particularly, DCS is more stable in a chemisorbed state than in a physisorbed state (in contrast to TSA as will be explained in detail in FIGS. 4A and 4B). Therefore as shown in FIG. 3D, a conformal film 360′ has a substantially identical film thickness along a patterned structure 350′ including a top 355′, a bottom 357′ and a sidewall 359′.

FIG. 4A shows a schematic of an absorption process 400A of SiN during ALD, and FIG. 4B shows an energy graph 400B of the absorption process in FIG. 4A in accordance with some embodiments of the present disclosure. As shown in state (a), —NH₂ groups are present on a surface, for example on the top 135, the bottom 137 and the sidewall 139 of the patterned structure 133. Some —NH₂ groups may be adjacent to —NH groups. State (a) has an energy of 0 eV.

In state (b), a molecule of trisilylamine (TSA) is physically absorbed to the —NH₂ groups. State (b) denoting physisorption has an energy of −0.57 eV. Physisorbed TSA cannot react with —NH₂ groups in a thermal process.

In state (c), a silicon-nitrogen bond is formed between a TSA molecule and a —NH₂ group. As a result, an H atom of the —NH₂ group may migrate towards a neighboring-NH group. State (c) has an energy of −0.07 eV.

In state (d), the —NH₂ group loses an H atom to the neighboring-NH group. State (d) has an energy of 0.10 eV.

In state (e), a gaseous molecule of HN(SiH₃)₂ is produced and released, leaving a —HN—SiH₃ group on the surface. State (e) denoting chemisorption has an energy of −0.47 eV.

As discussed earlier in block 211, TSA can react with —NH₂ surface groups to form an intermediate layer of an ALD cycle. Specifically, the intermediate layer can include states (a), (b), (c), (d) and (e), with state (b) in the most abundance in an equilibrium state due to its lowest energy. Nevertheless, physisorbed TSA in state (b) cannot react with the nitrogen precursor in block 223 whereas chemisorbed TSA in state (e) can.

State (b) is more stable and favorable than state (e) since state (b) has a lower energy than state (e). Additionally, an activation energy of converting from physisorption (b) to chemisorption (e) is Eₐ=0.10 eV−(−0.57 eV)=0.67 eV, which is a relatively big energy barrier and thus further favors state (b). In other words, TSA will be easily forced to go backwards from a chemisorbed state (e) to a physisorbed state (b).

However, H⁺ ions generated in block 221 in FIG. 2 and/or from the hydrogen ion source 123 in FIG. 1A can shift the equilibrium from state (b) to state (e), therefore enhancing the reaction with the nitrogen precursor in block 223 and promoting film growth.

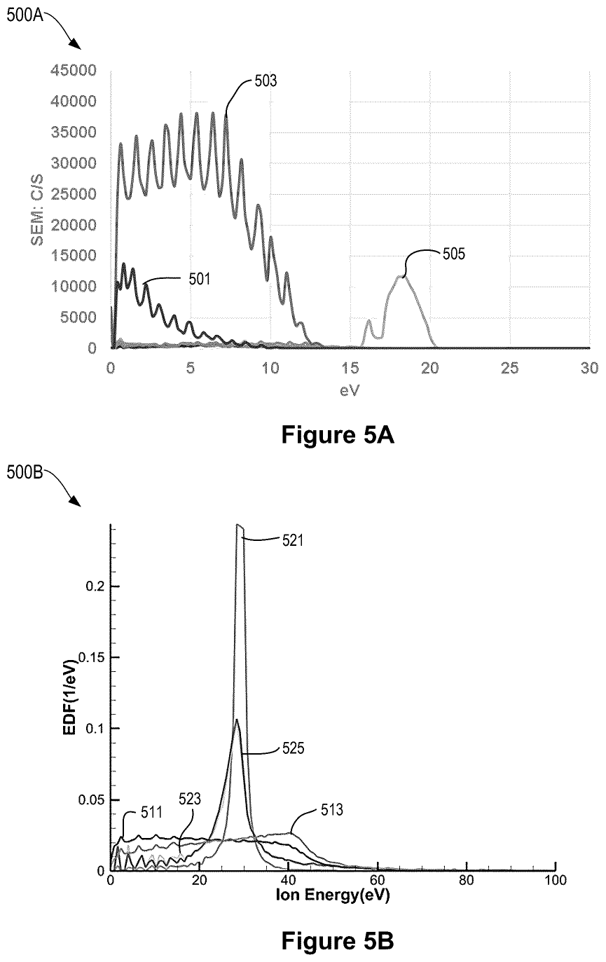

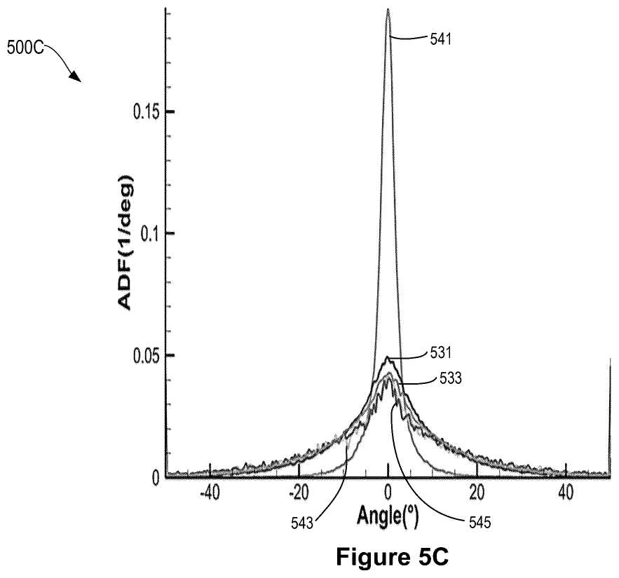

FIG. 5A shows an ion energy distribution 500A of a plasma in accordance with some embodiments of the present disclosure. Data were collected by ion mass spectroscopy under conditions of 200 MHz, 600 mTorr, 1000 standard cubic centimeter per minute (sccm) of Ar, 625 sccm of N₂ and 25 sccm of CH₄. Lines 501, 503 and 505 respectively represent Ar⁺ ions, N₂⁺ ions and H⁺ ions. As can be seen, H⁺ ions have a substantially monotonic energy distribution. In other words, the H⁺ ions have a relatively narrow energy distribution compared with Art ions and N₂⁺ ions. An average energy of the H⁺ ions is about 18 eV, indicating no or little collision in the sheath.

FIG. 5B shows ion kinetic simulation results of an ion energy distribution function (IEDF) 500B of a plasma in accordance with some embodiments of the present disclosure. Lines 511, 513, 521, 523 and 525 respectively represent Ar⁺ ions, N₂⁺ ions, H⁺ ions, H₂⁺ ions and H₃⁺ ions. Similarly, the H⁺ ions can have a substantially monotonic energy distribution. An average energy of the H⁺ ions is about 28 eV. At least 80%, preferably at least 85%, preferably at least 90%, preferably at least 95% of the H⁺ ions are within an energy range of 25-31 eV.

FIG. 5C shows ion kinetic simulation results of an ion angular distribution function (IADF) 500C of the plasma in FIG. 5B in accordance with some embodiments of the present disclosure. Lines 531, 533, 541, 543 and 545 respectively represent Ar⁺ ions, N₂⁺ ions, H⁺ ions, H₂⁺ ions and H₃⁺ ions. The H⁺ ions have an anisotropic angular distribution. More specifically, the H⁺ ions can be substantially unidirectional, with an average angle of about 0°. At least 80%, preferably at least 85%, preferably at least 90%, preferably at least 95% of the H⁺ ions are within an angular range of −5° to 5°.

As can be seen in FIGS. 5A-5C, H⁺ ions dominate the hydrogen ions (e.g. H⁺, H₂⁺ and H₃⁺ ions), have a substantially monotonic energy distribution and hardly collide in the sheath. H⁺ ions are substantially unidirectional and can thus enable anisotropic bombardment of the top 135 and the bottom 137.

Note that the plasma containing the H⁺ ions is generated at or above 100 MHz (e.g. very high frequency (VHF), ultra-high frequency (UHF) or microwave frequency) to reduce ion energy induced damage of a surface layer (e.g. 340 in FIG. 3A and state (e) in FIG. 4A). Plasma of a higher frequency tends to result in lower energy as well as better unidirectionality of the H⁺ ions. The plasma can have a frequency of 100 MHz to 10 GHz such as 100 MHz, 150 MHz, 200 MHz, 300 MHz, 400 MHZ, 500 MHz, 600 MHz, 800 MHZ, 1 GHZ, 5 GHz, 10 GHz, or any value therebetween. The plasma can be generated at a temperature of −273.15° C. to 500° C. such as −273.15° C., −200° C., −100° C., 0° C., 100° C., 200° C., 300° C., 400° C., 450° C., 500° C., or any value therebetween.

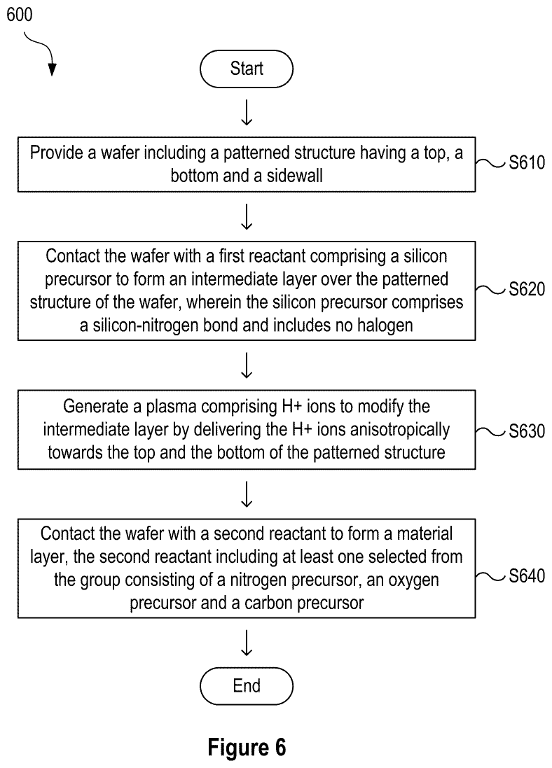

FIG. 6 shows a flow chart of a process 600 of film deposition in accordance with some embodiments of the present disclosure. At step S610, a wafer is provided that includes a patterned structure having a top, a bottom and a sidewall. At step S620, the wafer is contacted with a first reactant including a silicon precursor to form an intermediate layer over the patterned structure of the wafer. The silicon precursor includes a silicon-nitrogen bond and includes no halogen. At step S630, a plasma including H⁺ ions is generated to modify the intermediate layer by delivering the H⁺ ions anisotropically towards the top and the bottom of the patterned structure. At step S640, the wafer is contacted with a second reactant to form a material layer. The second reactant includes at least one selected from the group consisting of a nitrogen precursor, an oxygen precursor and a carbon precursor. A film can be formed on the wafer by a cyclical deposition process including a cycle of step S620, step S630 and step S640.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of film deposition, the method comprising:
providing a wafer including a patterned structure having a top, a bottom and a sidewall; and
forming a film on the wafer by a cyclical deposition process comprising a cycle of:
contacting the wafer with a first reactant comprising a silicon precursor to form an intermediate layer over the patterned structure of the wafer, wherein the silicon precursor comprises a silicon-nitrogen bond and includes no halogen;
generating a plasma comprising H⁺ ions to modify the intermediate layer by delivering the H⁺ ions anisotropically towards the top and the bottom of the patterned structure; and
contacting the wafer with a second reactant to form a material layer, the second reactant including at least one selected from the group consisting of a nitrogen precursor, an oxygen precursor and a carbon precursor.

2. The method of claim 1, wherein:
the silicon precursor consists of silicon (Si), nitrogen (N), hydrogen (H) and carbon (C) or consists of Si, N and H.

3. The method of claim 2, wherein:
the silicon precursor includes at least one of trisilylamine (TSA) or a molecule conforming to a formula of Si(NR¹R²)ₙ(R³)₄₋ₙ, where
n is 1, 2, 3 or 4, and
R¹, R², and R³ are each independently a hydrogen atom or an alkyl group having 1-18 carbon atoms.

4. The method of claim 3, wherein:
the silicon precursor includes at least one selected from the group consisting of TSA, bis(tertiary-butylamino) silane (BTBAS), bis(diethylamino) silane (BDEAS) and bis(dimethylamino)dimethylsilane (BDMADMS).

5. The method of claim 1, further comprising:
generating the plasma from a gas including at least one selected from the group consisting of H₂ and a hydrocarbon.

6. The method of claim 5, wherein:
the gas includes at least one selected from the group consisting of H₂, benzene, a benzene derivative having 7 to 10 carbon atoms, and an alkane having 1 to 18 carbon atoms.

7. The method of claim 6, wherein:
the gas includes H₂, CH₄ or a combination thereof.

8. The method of claim 5, wherein:
the plasma further comprises H₂⁺ and H₃⁺ ions.

9. The method of claim 1, further comprising:
generating the plasma at a frequency of 100 MHz to 10 GHz.

10. The method of claim 9, wherein:
the H⁺ ions are substantially unidirectional so that the H⁺ ions are delivered substantially towards the top and the bottom of the patterned structure, relative to the sidewall of the patterned structure.

11. The method of claim 10, wherein:
the H⁺ ions have a substantially monotonic energy distribution that is configured to promote film deposition at the top and the bottom of the patterned structure.

12. The method of claim 1, wherein:
the cyclical deposition process includes repeating the cycle for at least one more time.

13. The method of claim 12, wherein:
the film is thicker at the top and the bottom of the patterned structure than at the sidewall of the patterned structure.

14. The method of claim 1, wherein:
the plasma is generated before or while the wafer is contacted with the second reactant.

15. The method of claim 1, wherein:
the cyclical deposition process is executed at a temperature of no higher than 500° C.

16. The method of claim 1, wherein:
the cyclical deposition process comprises atomic layer deposition.

17. The method of claim 1, further comprising:
forming —NH₂ surface groups on the patterned structure of the wafer.

18. The method of claim 1, wherein:
the material layer comprises one selected from the group consisting of silicon nitride, silicon oxide, silicon oxynitride and silicon carbide.

19. The method of claim 18, wherein:
the material layer comprises silicon nitride, and
the second reactant comprises a nitrogen precursor.

20. An apparatus, comprising a controller including a processor that is programmed to:
provide a wafer including a patterned structure having a top, a bottom and a sidewall; and
form a film on the wafer by a cyclical deposition process comprising a cycle of:
contacting the wafer with a first reactant comprising a silicon precursor to form an intermediate layer over the patterned structure of the wafer, wherein the silicon precursor comprises a silicon-nitrogen bond and includes no halogen;
generating a plasma comprising H⁺ ions to modify the intermediate layer by delivering the H⁺ ions anisotropically towards the top and the bottom of the patterned structure; and
contacting the wafer with a second reactant to form a material layer, the second reactant including at least one selected from the group consisting of a nitrogen precursor, an oxygen precursor and a carbon precursor.
